(19) United States
(12) Patent Application Publication
(10) Pub. No.: US 2019/0226643 A1
(43) Pub. Date: Jul. 25, 2019

(54) LED FILAMENT

(71) Applicant: Katerra Inc., Menlo Park, CA (US)

(72) Inventor: Juntao Zheng, Shanghai (CN)

(73) Assignee: Katerra Inc., Menlo Park, CA (US)

(21) Appl. No.: 16/250,727

(22) Filed: Jan. 17, 2019

Related U.S. Application Data
(63) Continuation of application No. PCT/CN2016/009814, filed on Sep. 13, 2016.

(30) Foreign Application Priority Data
Jul. 19, 2016 (CN) 2016105706706
Jul. 19, 2016 (CN) 2016207629377

(51) Int. Cl. F21K 9/232; H05K 1/02; H05K 1/18

(52) U.S. Cl. CPC F21K 9/232; H05K 1/189; H05K 1/0274

(57) ABSTRACT

The invention relates to the technical field of lighting, and more particularly, to an LED filament, disposed in a light bulb. The LED filament comprises: a flexible circuit board; a plurality of chips distributed on the flexible circuit board, each chip being coated with fluorescent powder, and the plurality of chips driving the fluorescent powder to emit light. In the present invention, a flexible LED filament is formed by using a specific flexible circuit board, and attaching chips and fluorescent powder to the flexible circuit board. The formed LED filament can be arranged in a light bulb in any specific shape, solving the problem of light emitted from the LED filament light being uneven and light distribution, such that the formed LED filament light realizes 360 degrees light emission without a dead corner, with uniform luminance.

### BACKGROUND OF THE INVENTION

### 1. Field of the Invention

The invention relates to the field of lighting technology, and more particularly, to an LED filament.

### 2. Description of the Related Art

Recent years have witnessed global population growth and sustained economic growth, which inevitably leads to issues of energy shortage and environmental pollution. Therefore, it is our great responsibility to tackle such environmental concern and enhance energy conservation worldwide. As a revolutionary technological innovation, LEDs (light-emitting diodes) have been introduced into the lighting applications. LED lighting products have many advantages over the traditional lighting products, including lower energy consumption and longer lifetime; furthermore, they have fewer environmental concerns and produce less heat, therefore LED filament lights are replacing the traditional lighting products such as the incandescent lights.

However, LED filaments used in the available LED filament lights are typically non-flexible filament strips. Production of such filament strips involves complicated process steps, and they have complex structures and won't be bent, as a result, there is great limitation when it comes to arrangement in the light bulbs, and light produced by LED filaments are further uneven, whereby light distribution cannot be met as expected.

### SUMMARY OF THE INVENTION

In order to solve the abovementioned technical problems, the present invention intends to provide a flexible LED filament. In this invention, specialized filament strips are utilized to make an arrangement of an especial shape, so as to solve the problems of uneven light emission and light distribution.

The technical solutions to solving the above technical problems are as follows:

an LED filament disposed in a light bulb, comprising:

a flexible circuit board; and

a plurality of chips distributed on the flexible circuit board, each chip being coated with fluorescent powder, and the plurality of chips driving the fluorescent powder to emit light.

Preferably, in the LED filament, the flexible circuit board comprises a conductive circuit, and the conductive circuit is electrically connected to each of the plurality of chips.

Preferably, in the LED filament, the flexible circuit board is a printed circuit board or a thin metal substrate.

Preferably, in the LED filament, the fluorescent powder is distributed in blocks separated from one another or in strips on the flexible circuit board.

Preferably, in the LED filament, the plurality of chips are flip chips, and the fluorescent powder is coated on a back side of each of the plurality of chips.

Preferably, in the LED filament, the plurality of chips are surface mount chips, and the fluorescent powder is coated on a surface of each of the plurality of surface mount chips.

Preferably, in the LED filament, the flexible circuit board has a thickness in a range from 0.2 mm to 0.5 mm, and has a width in a range from 2 mm to 15 mm.

Preferably, in the LED filament, the flexible circuit board is made of copper or aluminum.

Preferably, the LED filament is vertically arranged in the light bulb in the form of a double helix cone.

Preferably, the LED filament is vertically arranged in the light bulb in the form of a single helix cone.

Preferably, the LED filament is arranged in the light bulb in the form of a single helix with cones at two ends.

Preferably, the LED filament is arranged in the light bulb in the form of a double helix with cones at two ends.

Preferably, the LED filament is annularly arranged in the light bulb

Preferably, the LED filament is fixed in the light bulb through a stem.

Preferably, the light bulb is mounted on a light holder, and the LED filament is electrically connected to the power source disposed in the light holder by spot welding or soldering.

The technical solution has the following advantages or beneficial effects: a flexible LED filament is formed by using a specific flexible circuit board, and attaching chips and fluorescent powder to the flexible circuit board. The formed LED filament can be arranged in a light bulb in any specific shape, solving the problem of light emitted from the LED filament light being uneven and light distribution, such that the formed LED filament light realizes 360 degrees light emission without a dead corner, with uniform luminance.

### BRIEF DESCRIPTION OF THE DRAWINGS

The accompanying drawings, together with the specification, illustrate exemplary embodiments of the present disclosure, and, together with the description, serve to explain the principles of the present invention.

FIGS. 1a and 1b are two different structural diagrams of an LED filament according to the present invention;

FIGS. 2-6 are schematic diagrams of different arrangements of an LED filament in a light bulb according to the present invention.

### DETAILED DESCRIPTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

Hereinafter, certain exemplary embodiments according to the present disclosure will be described with reference to the accompanying drawings.

An LED filament provided in the present invention comprises a flexible circuit board 10, preferably a PCB (Printed Circuit Board), and a plurality of chips, uniformly distributed on a surface of the printed circuit board 10 on which a conductive circuit is provided, and fluorescent powder, being coated on the surface of each of the plurality of chips.

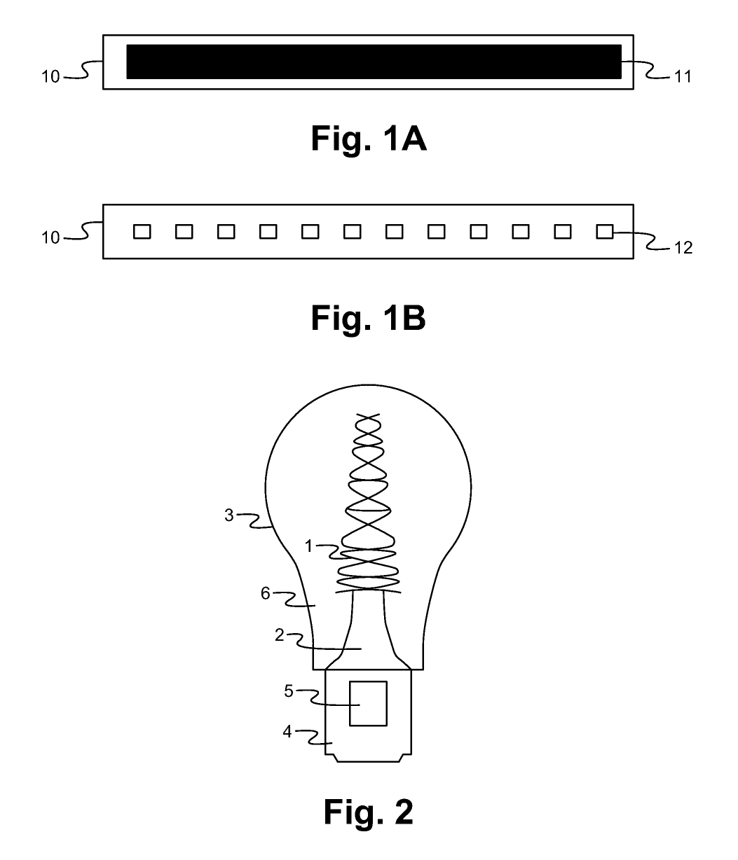

The plurality of chips are SMD (Surface Mounted Device) chips, and the fluorescent powder is coated on a surface of each of the plurality of SMD (Surface Mounted Device) chips; or the plurality of chips are flip chips, and the fluorescent powder is coated on a back side of each of the plurality of chips. More preferably, the plurality of chips (since the surface of the plurality of chips is coated with the fluorescent powder, the chips cannot be shown in the figure) are divided into a plurality of pieces to be uniformly distributed on the PCB. After the plurality of chips are coated with the fluorescent powder, an entire fluorescent strip 11 as shown in FIG. 1a or a plurality of blocks as shown in FIG. 1b may be formed. It should be noted that FIG. 1a shows two types of LED filaments, which are formed after the process that the plurality of chips are coated with the fluorescent powder, wherein reference numeral 11 represents that the fluorescent powder is evenly and continuously coated onto the surface of the block-shaped chips and the surface of an exposed part of the PCB 10, so as to form an entire fluorescent strip; reference numeral 12 shown in FIG. 1b represents that the fluorescent powder is coated only onto the surface of the block-shape chips to form a plurality of block-shaped fluorescent regions which are spaced apart from one another at an equal distance.

As a preferred embodiment, PCB 10 may be a flexible printed circuit or a thin metal substrate that can be folded into any shapes, and the PCB 10 has a thickness in a range from 0.2 mm to 0.5 mm and a width in a range from 2 mm to 15 mm, and it is made of copper or aluminum. The use of a PCB circuit board that can be folded into any shapes can greatly simplify the processing steps and the structural complexity of the PCB. Moreover, when the filament light is assembled, a filament made of the PCB that can be folded into any shapes, can be arranged in the light bulb in a bent configuration. In this manner, limitation of the arrangement of the LED filament in the light bulb can be overcome, so as to ensure uniform luminance of the formed LED filament light.

With reference to FIGS. 2-6, when assembling the LED filament light, the LED filament (hereinafter referred to as filament 1) in the present invention is fixed in the light bulb 3 (also known as a light shell) through a stem 2. The light bulb 3 is fixed above the light holder 4, and power supply 5 is embedded in the light holder 4. The filament 1 is electrically connected to the power supply 5 by spot welding or soldering, thus, the power supply 5 may provide electric energy to the filament 1. The light bulb is filled with thermal conductive gas 6.

As a preferred embodiment, since the PCB 10 can be folded into any shapes, when the LED filament light is assembled, the arrangement of the filament 1 in the light bulb 3 can be flexibly changed. As shown in FIG. 2, the filament 1 vertically arranged in the light bulb 3 in the form of a double helix cone, such that 360 degrees light emission without a dead corner, with uniform luminance can be achieved;

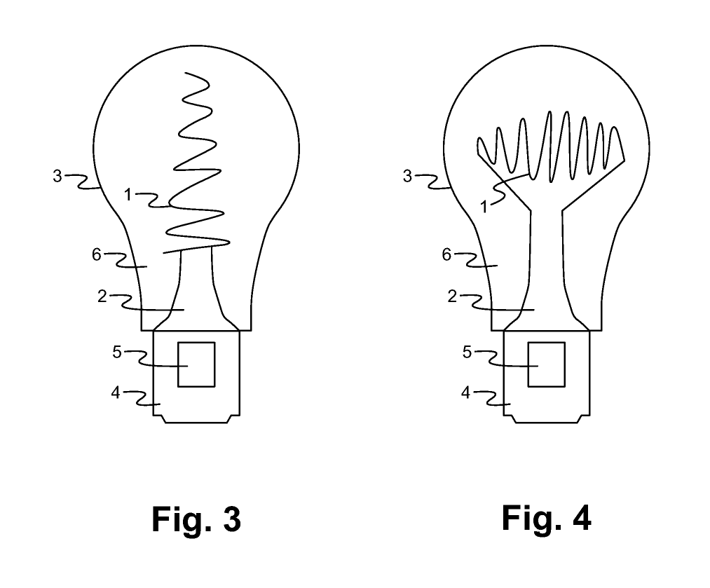

or as shown in FIG. 3, the filament 1 is arranged in the light bulb 3 in the form of a single helix cone, through which 360 degrees light emission without a dead corner, with uniform luminance can also be achieved.

or as shown in FIG. 4, the filament 1 is arranged in the light bulb 3 in the form of a single helix with cones at two ends, through which 360 degrees light emission without a dead corner, with uniform luminance can also be achieved.

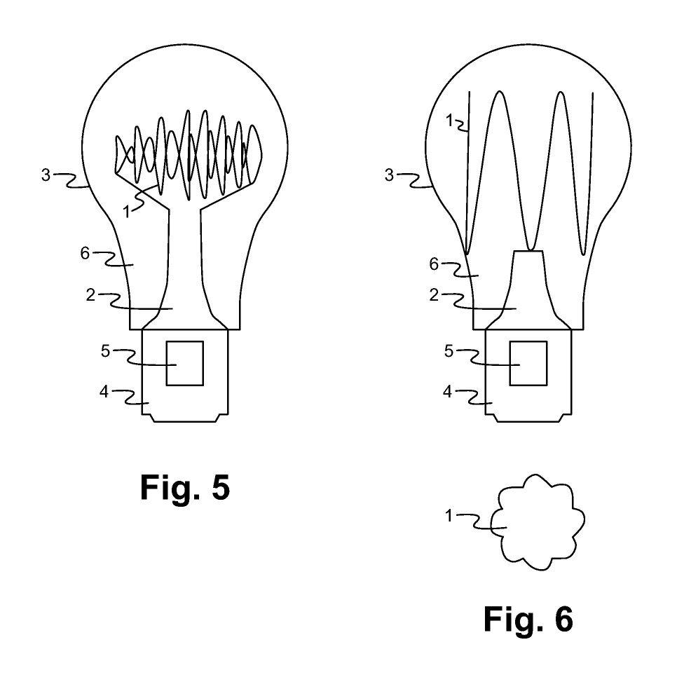

or as shown in FIG. 5, the filament 1 is arranged in the light bulb 3 in the form of a double helix with cones at two ends, through which 360 degrees light emission without a dead corner, with uniform luminance can also be achieved;

or as shown in FIG. 6, the filament 1 is annularly arranged in the light bulb 3 (the filament 1 resembles a flower when viewed from above), through which 360 degrees light emission without a dead corner, with uniform luminance can also be achieved.

In conclusion, in the flexible LED filament that can be folded into any shapes according to the present invention, by using a specific flexible circuit board, and attaching chips and fluorescent powder to the flexible circuit board to form an LED filament, the formed LED filament can be arranged in a light bulb in any specific shape, solving the problem of light emitted from the LED filament light being uneven and light distribution, such that the formed LED filament light realizes 360 degrees light emission without a dead corner, with uniform luminance.

The above descriptions are only the preferred embodiments of the invention, not thus limiting the embodiments and scope of the invention. Those skilled in the art should be able to realize that the schemes obtained from the content of specification and drawings of the invention are within the scope of the invention.

What is claimed is:

1. An LED filament disposed in a light bulb, comprising:
a flexible circuit board; and
a plurality of chips distributed on the flexible circuit board, each chip being coated with fluorescent powder, and the plurality of chips driving the fluorescent powder to emit light.

2. The LED filament as claimed in claim 1, wherein the flexible circuit board comprises a conductive circuit, and the conductive circuit is electrically connected to each of the plurality of chips.

3. The LED filament as claimed in claim 1, wherein the flexible circuit board is a printed circuit board or a thin metal substrate.

4. The LED filament as claimed in claim 1, wherein the fluorescent powder is distributed in blocks separated from one another or in strips on the flexible circuit board.

5. The LED filament as claimed in claim 1, wherein the plurality of chips are flip chips, and the fluorescent powder is coated on a back side of each of the plurality of chips.

6. The LED filament as claimed in claim 1, wherein the plurality of chips are surface mounted chips, and the fluorescent powder is coated on a surface of each of the plurality of surface mounted chips.

7. The LED filament as claimed in claim 1, wherein the flexible circuit board has a thickness a range from 0.2 mm to 0.5 mm, and has a width in a range from 2 mm to 15 mm.

8. The LED filament as claimed in claim 1 wherein the flexible circuit board is made of copper or aluminum.

9. The LED filament as claimed in claim 1, wherein the LED filament is vertically arranged in the light bulb in the form of a double helix cone.

10. The LED filament as claimed in claim 1, wherein the LED filament is vertically arranged in the light bulb in the form of a single helix cone.

11. The LED filament as claimed in claim 1, wherein the LED filament is arranged in the light bulb in the form of a single helix with cones at two ends.

12. The LED filament as claimed in claim 1, wherein the LED filament is arranged in the light bulb in the form of a double helix with cones at two ends.

13. The LED filament as claimed in claim 1, wherein the LED filament is annularly arranged in the light bulb.

14. The LED filament as claimed in claim 1, wherein the LED filament is fixed in the light bulb through a stem.

15. The LED filament as claimed in claim 1, wherein the light bulb is mounted on a light holder, and the LED filament is electrically connected to the power source disposed in the light holder by spot welding or soldering.
